(19) United States
(12) Patent Application Publication
(10) Pub. No.: US 2026/0098914 A1
(43) Pub. Date: Apr. 9, 2026

(54) SYSTEMS AND METHODS FOR BATTERY INTERNAL SOFT SHORT DETECTION

(71) Applicant: GM GLOBAL TECHNOLOGY OPERATIONS LLC, Detroit, MI (US)

(72) Inventors: Xinyu Du, Oakland Township, MI (US); Shiming Duan, Ann Arbor, MI (US); Huaizheng Mu, Troy, MI (US); Shengbing Jiang, Rochester Hills, MI (US); Chaitanya Sankavaram, Rochester Hills, MI (US); Rasoul Salehi, Ann Arbor, MI (US); Yaqing Xu, Clawson, MI (US)

(73) Assignee: GM GLOBAL TECHNOLOGY OPERATIONS LLC, Detroit, MI (US)

(21) Appl. No.: 18/905,303

(22) Filed: Oct. 3, 2024

(51) Int. Cl. G01R 31/52; B60R 16/033; G01R 31/3842; G01R 31/396; H01M 10/42; H01M 10/48

(52) U.S. Cl. CPC G01R 31/52; G01R 31/3842; G01R 31/396; H01M 10/4285; H01M 10/482; B60R 16/033; H01M 2220/20

(57) ABSTRACT

Cell group voltages for battery cell groups of a battery module are received from voltage sensors. Cell group currents for the battery cell groups are received from current sensors. Open circuit voltages are generated for each of the battery cell groups based on the cell group voltages and the cell group currents. A normalized open circuit voltage of a first battery cell group of the battery cell groups is generated based on the open circuit voltages of the battery cell groups. A normalized cell group voltage of the first battery cell group is generated based on the cell group voltages of the battery cell groups. An assessment of the normalized open circuit voltage and the normalized cell group voltage of the first battery cell group is performed to determine whether there is an internal soft short in the first battery cell group.

### INTRODUCTION

The technical field generally relates to vehicles, and more particularly relates to systems and methods for battery internal soft short detection in a vehicle.

Lithium-ion batteries are typically used in electric vehicles. An internal soft short in a battery results from a degradation of an electrical connection between an anode and a cathode of a battery and may be an early indication of a failure that may lead to an internal hard short. An internal hard short occurs when there is a complete short between the anode and the cathode of the battery.

Accordingly, it is desirable to provide systems and methods for battery internal short detection in a battery prior to the degradation of the battery to an internal hard short. Other desirable features and characteristics will become apparent from the subsequent detailed description and the appended claims, taken in conjunction with the accompanying drawings and the foregoing technical field and background.

### SUMMARY

A battery internal soft short detection system includes at least one processor and at least one memory communicatively coupled to the at least one processor. The at least one memory includes instructions that upon execution by the at least one processor, cause the at least one processor to: receive cell group voltages for a plurality of battery cell groups of a battery module from a plurality of voltage sensors; receive cell group currents for the plurality of battery cell groups from a plurality of current sensors; generate open circuit voltages for each of the plurality of battery cell groups based on the cell group voltages and the cell group currents; generate a normalized open circuit voltage of a first battery cell group of the plurality of battery cell groups based on the open circuit voltages of the plurality of battery cell groups; generate a normalized cell group voltage of the first battery cell group based on the cell group voltages of the plurality of battery cell groups; and determine whether there is an internal soft short in the first battery cell group based on an assessment of the normalized open circuit voltage and the normalized cell group voltage of the first battery cell group.

In at least one embodiment, the at least one memory further includes instructions that upon execution by the at least one processor, cause the at least one processor to during the assessment: determine whether a first rule is true based on one of at least one of a first equation and a second equation being true,
the first equation being:

$$F = ( \vert z ( mm O C V ) \vert > {T}_{1} ) and ( \vert z ( \frac{d ( mm c g V )}{dt} ) \vert > {T}_{2}$$

wherein mmOCV is the normalized open circuit voltage of the first battery cell group, T₁ is a first threshold number of standard deviations, mmcgV is the normalized cell group voltage of the first battery cell group, and T₂ is a second threshold number of standard deviations;
the second equation being:

$$F = ( \vert z ( mm O C V ) \vert > {T}_{1} ) and \vert z ( Δ mm c g V ) \vert > {T}_{3}$$

wherein a cell group voltage pulse is detected in a cell group voltage of the first battery cell group and the change in the normalized cell group voltage of the first battery cell group is associated with the cell group voltage pulse, and the T₃ is a third threshold number of standard deviations; and identify the first battery cell group as an outlier battery cell group in the battery module based on the first rule being true.

In at least one embodiment, the at least one memory further includes instructions that upon execution by the at least one processor, cause the at least one processor to during the assessment: determine whether a second rule is true based on one of at least one of a third equation and a fourth equation being true,
the third equation being:

$$F = ( mm O C V < {T}_{4} ) and ( \vert \frac{d ( mm c g V )}{dt} \vert > {T}_{5} )$$

wherein T₄ is a normalized open circuit voltage threshold and T₅ is a rate of change of a normalized cell group voltage threshold;
the fourth equation being:

$$F = ( mm O C V < {T}_{4} ) and ( \vert Δ mm c g V \vert > {T}_{6} )$$

wherein T₆ is a change in normalized cell group voltage threshold; and determine that there is the internal soft short in the first battery cell group based the first rule and the second rule being true.

In at least one embodiment, the at least one memory further includes instructions that upon execution by the at least one processor, cause the at least one processor to perform outlier removal of outlier cell group voltage values from a cell group voltage associated with the first battery cell group prior to generation of the normalized cell group voltage of the first battery cell group.

In at least one embodiment, the at least one memory further includes instructions that upon execution by the at least one processor, cause the at least one processor to perform data down sample and alignment of a cell group voltage and a cell group current associated with the first battery cell group prior to generation of the normalized cell group voltage of the first battery cell group.

In at least one embodiment, the at least one memory further includes instructions that upon execution by the at least one processor, cause the at least one processor to perform linear interpolation of the cell group voltage and the cell group current associated with the first battery cell group prior to generation of the normalized cell group voltage of the first battery cell group.

In at least one embodiment, the at least one memory further includes instructions that upon execution by the at least one processor, cause the at least one processor to perform low pass filtering of the cell group voltage and the cell group current associated with the first battery cell group prior to generation of the normalized first cell group voltage of the first battery cell group.

In at least one embodiment, the at least one memory further includes instructions that upon execution by the at least one processor, cause the at least one processor to perform thermal compensation of an open circuit voltage the first battery cell group prior to generation of the normalized open circuit voltage.

A method of detecting an internal soft short in a battery cell group includes: receiving cell group voltages for a plurality of battery cell groups of a battery module from a plurality of voltage sensors; receiving cell group currents for the plurality of battery cell groups from a plurality of current sensors; generating open circuit voltages for each of the plurality of battery cell groups based on the cell group voltages and the cell group currents; generating a normalized open circuit voltage of a first battery cell group of the plurality of battery cell groups based on the open circuit voltages of the plurality of battery cell groups; generating a normalized cell group voltage of the first battery cell group based on the cell group voltages of the plurality of battery cell groups; and determining whether there is an internal soft short in the first battery cell group based on an assessment of the normalized open circuit voltage and the normalized cell group voltage of the first battery cell group.

In at least one embodiment, the method further includes: during the assessment, determining whether a first rule is true based on one of at least one of a first equation and a second equation being true,
the first equation being:

$$F = ( \vert z ( mm O C V ) \vert > {T}_{1} ) and ( \vert z ( \frac{d ( mm c g V )}{dt} ) \vert > {T}_{2}$$

wherein mmOCV is the normalized open circuit voltage of the first battery cell group, T₁ is a first threshold number of standard deviations, mmcgV is the normalized cell group voltage of the first battery cell group, and T₂ is a second threshold number of standard deviations;
the second equation being:

$$F = ( \vert z ( mm O C V ) \vert > {T}_{1} ) and \vert z ( Δ mm c g V ) \vert > {T}_{3}$$

wherein a cell group voltage pulse is detected in a cell group voltage of the first battery cell group and the change in the normalized cell group voltage of the first battery cell group is associated with the cell group voltage pulse, and the T₃ is a third threshold number of standard deviations; and identifying the first battery cell group as an outlier battery cell group in the battery module based on the first rule being true.

In at least one embodiment, the method further includes during the assessment, determining whether a second rule is true based on one of at least one of a third equation and a fourth equation being true,
the third equation being:

$$F = ( mm O C V < {T}_{4} ) and ( \vert \frac{d ( mm c g V )}{dt} \vert > {T}_{5} )$$

wherein T₄ is a normalized open circuit voltage threshold and T₅ is a rate of change of a normalized cell group voltage threshold;
the fourth equation being:

$$F = ( mm O C V < {T}_{4} ) and ( \vert Δ mm c g V \vert > {T}_{6} )$$

wherein T₆ is a change in normalized cell group voltage threshold; and determine that there is the internal soft short in the first battery cell group based the first rule and the second rule being true.

In at least one embodiment, the method further includes performing outlier removal of outlier cell group voltage values from a cell group voltage associated with the first battery cell group prior to generation of the normalized cell group voltage of the first battery cell group.

In at least one embodiment, the method further includes performing data down sample and alignment of a cell group voltage and a cell group current associated with the first battery cell group prior to generation of the normalized cell group voltage of the first battery cell group.

In at least one embodiment, the method further includes performing linear interpolation of the cell group voltage and the cell group current associated with the first battery cell group prior to generation of the normalized cell group voltage of the first battery cell group.

In at least one embodiment, the method further includes performing low pass filtering of the cell group voltage and the cell group current associated with the first battery cell group prior to generation of the normalized first cell group voltage of the first battery cell group.

In at least one embodiment, the method further includes performing thermal compensation of an open circuit voltage the first battery cell group prior to generation of the normalized open circuit voltage.

A vehicle including a battery internal soft short detection system includes at least one processor and at least one memory communicatively coupled to the at least one processor. The at least one memory includes instructions that upon execution by the at least one processor, cause the at least one processor to: receive cell group voltages for a plurality of battery cell groups of a battery module from a plurality of voltage sensors; receive cell group currents for the plurality of battery cell groups from a plurality of current sensors; generate open circuit voltages for each of the plurality of battery cell groups based on the cell group voltages and the cell group currents; generate a normalized open circuit voltage of a first battery cell group of the plurality of battery cell groups based on the open circuit voltages of the plurality of battery cell groups; generate a normalized cell group voltage of the first battery cell group based on the cell group voltages of the plurality of battery cell groups; and determine whether there is an internal soft short in the first battery cell group based on an assessment of the normalized open circuit voltage and the normalized cell group voltage of the first battery cell group.

In at least one embodiment, the at least one memory further includes instructions that upon execution by the at least one processor, cause the at least one processor to during the assessment: determine whether a first rule is true based on one of at least one of a first equation and a second equation being true,
the first equation being:

$$F = ( \vert z ( mm O C V ) \vert > {T}_{1} ) and ( \vert z ( \frac{d ( mm c g V )}{dt} ) \vert > {T}_{2}$$

wherein mmOCV is the normalized open circuit voltage of the first battery cell group, T₁ is a first threshold number of standard deviations, mmcgV is the normalized cell group voltage of the first battery cell group, and T₂ is a second threshold number of standard deviations;
the second equation being:

$$F = ( \vert z ( mm O C V ) \vert > {T}_{1} ) and \vert z ( Δ mm c g V ) \vert > {T}_{3}$$

wherein a cell group voltage pulse is detected in a cell group voltage of the first battery cell group and the change in the normalized cell group voltage of the first battery cell group is associated with the cell group voltage pulse, and the T₃ is a third threshold number of standard deviations; and identify the first battery cell group as an outlier battery cell group in the battery module based on the first rule being true.

In at least one embodiment, the at least one memory further includes instructions that upon execution by the at least one processor, cause the at least one processor to during the assessment: determine whether a second rule is true based on one of at least one of a third equation and a fourth equation being true,
the third equation being:

$$F = ( mm O C V < {T}_{4} ) and ( \vert \frac{d ( mm c g V )}{dt} \vert > {T}_{5} )$$

wherein T₄ is a normalized open circuit voltage threshold and T₅ is a rate of change of a normalized cell group voltage threshold;
the fourth equation being:

$$F = ( mm O C V < {T}_{4} ) and ( \vert Δ mm c g V \vert > {T}_{6} )$$

wherein T₆ is a change in normalized cell group voltage threshold; and determine that there is the internal soft short in the first battery cell group based the first rule and the second rule being true.

In at least one embodiment, the at least one memory further includes instructions that upon execution by the at least one processor, cause the at least one processor to perform data down sample and alignment of a cell group voltage and a cell group current associated with the first battery cell group prior to generation of the normalized cell group voltage of the first battery cell group.

### BRIEF DESCRIPTION OF THE DRAWINGS

The exemplary embodiments will hereinafter be described in conjunction with the following drawing figures, wherein like numerals denote like elements, and wherein:

FIG. 1 is a functional block diagram of a vehicle including a battery internal soft short detection system in accordance with at least one embodiment;

FIG. 2 is a functional block diagram of a controller including a battery internal soft short detection system in accordance with at least one embodiment;

FIG. 3 is a flowchart representation of a method of detecting an internal soft short in a battery cell group in accordance with at least one embodiment;

FIG. 4 is a graphical representation of exemplary cell group current and cell group voltage as a function of time following the performance of current-based segmentation in accordance with at least one embodiment;

FIG. 5a is a graphical representations of exemplary cell group current and cell group voltage as a function of time prior to performance of data down sample and alignment in accordance with at least one embodiment;

FIG. 5b is a graphical representations of exemplary cell group current and cell group voltage as a function of time following the performance of data down sample and alignment in accordance with at least one embodiment;

FIG. 6a is a graphical representations of exemplary cell group current and cell group voltage as a function of time prior to performance of linear interpolation in accordance with at least one embodiment;

FIG. 6b is a graphical representations of exemplary cell group current and cell group voltage as a function of time following the performance of linear interpolation in accordance with at least one embodiment;

FIG. 7a is a graphical representations of exemplary cell group current and cell group voltage as a function of time prior to performance of low pass filtering in accordance with at least one embodiment; and

FIG. 7b is a graphical representations of exemplary cell group current and cell group voltage as a function of time following performance of low pass filtering in accordance with at least one embodiment.

### DETAILED DESCRIPTION

The following detailed description is merely exemplary in nature and is not intended to limit the application and uses. Furthermore, there is no intention to be bound by any expressed or implied theory presented in the preceding technical field, background, brief summary or the following detailed description. As used herein, the term module refers to an application specific integrated circuit (ASIC), an electronic circuit, a processor (shared, dedicated, or group) and memory that executes one or more software or firmware programs, a combinational logic circuit, and/or other suitable components that provide the described functionality.

Embodiments of the present disclosure may be described herein in terms of functional and/or logical block components and various processing steps. It should be appreciated that such block components may be realized by any number of hardware, software, and/or firmware components configured to perform the specified functions. For example, an embodiment of the present disclosure may employ various integrated circuit components, e.g., memory elements, digital signal processing elements, logic elements, look-up tables, or the like, which may carry out a variety of functions under the control of one or more microprocessors or other control devices. In addition, those skilled in the art will appreciate that embodiments of the present disclosure may be practiced in conjunction with any number of systems, and that the systems described herein is merely exemplary embodiments of the present disclosure.

For the sake of brevity, conventional techniques related to signal processing, data transmission, signaling, control, and other functional aspects of the systems (and the individual operating components of the systems) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the present disclosure.

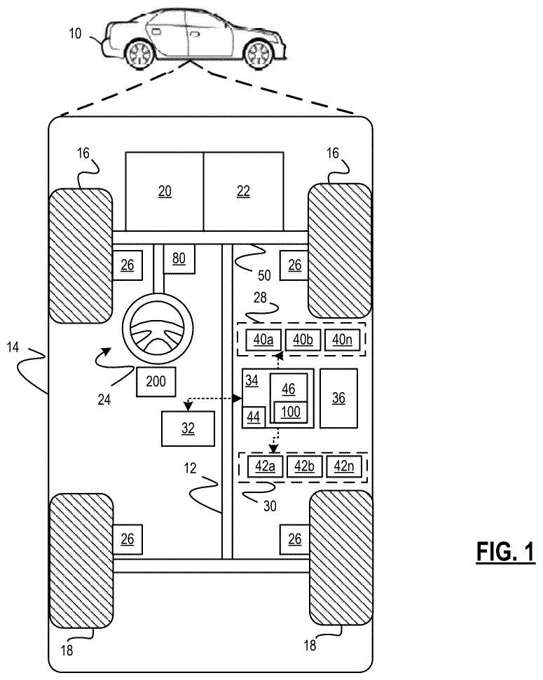

Referring to FIG. 1, a functional block diagram of a vehicle including a battery internal soft short detection system 100 in accordance with at least one embodiment is shown. The vehicle 10 generally includes a chassis 12, a body 14, front wheels 16, and rear wheels 18. While the vehicle 10 is depicted in the illustrated embodiment as a passenger car, the vehicle 10 may be other types of vehicles including trucks, sport utility vehicles (SUVs), and recreational vehicles (RVs).

In various embodiments, the body 14 is arranged on the chassis 12 and substantially encloses components of the vehicle 10. The body 14 and the chassis 12 may jointly form a frame. The wheels 16, 18 are each rotationally coupled to the chassis 12 near a respective corner of the body 14.

In various embodiments, the vehicle 10 is an autonomous or semi-autonomous vehicle that is automatically controlled to carry passengers and/or cargo from one place to another. For example, in an exemplary embodiment, the vehicle 10 is a so-called Level Two, Level Three, Level Four or Level Five automation system. Level two automation means the vehicle assists the driver in various driving tasks with driver supervision. Level three automation means the vehicle can take over all driving functions under certain circumstances. All major functions are automated, including braking, steering, and acceleration. At this level, the driver can fully disengage until the vehicle tells the driver otherwise. A Level Four system indicates “high automation”, referring to the driving mode-specific performance by an automated driving system of all aspects of the dynamic driving task, even if a human driver does not respond appropriately to a request to intervene. A Level Five system indicates “full automation”, referring to the full-time performance by an automated driving system of all aspects of the dynamic driving task under all roadway and environmental conditions that can be managed by a human driver.

As shown, the vehicle 10 generally includes a propulsion system 20 a transmission system 22, a steering system 24, a braking system 26, a sensor system 28, an actuator system 30, at least one data storage device 32, at least one controller 34, and a communication system 36. The controller 34 is configured to implement an automated driving system (ADS). The propulsion system 20 is configured to generate power to propel the vehicle. The propulsion system 20 may, in various embodiments, include an internal combustion engine, an electric machine such as a traction motor, a fuel cell propulsion system, and/or any other type of propulsion configuration. The transmission system 22 is configured to transmit power from the propulsion system 20 to the vehicle wheels 16, 18 according to selectable speed ratios. According to various embodiments, the transmission system 22 may include a step-ratio automatic transmission, a continuously-variable transmission, or other appropriate transmission. The braking system 26 is configured to provide braking torque to the vehicle wheels 16, 18. The braking system 26 may, in various embodiments, include friction brakes, brake by wire, a regenerative braking system such as an electric machine, and/or other appropriate braking systems.

The steering system 24 is configured to influence a position of the of vehicle wheels 16. While depicted as including a steering wheel and steering column, for illustrative purposes, in some embodiments contemplated within the scope of the present disclosure, the steering system 24 may not include a steering wheel and/or steering column. The steering system 24 includes a steering column coupled to an axle 50 associated with the front wheels 16 through, for example, a rack and pinion or other mechanism (not shown). Alternatively, the steering system 24 may include a steer by wire system that includes actuators associated with each of the front wheels 16.

The sensor system 28 includes one or more sensing devices 40a-40n that sense observable conditions of the exterior environment and/or the interior environment of the vehicle 10. The sensing devices 40a-40n can include, but are not limited to, radars, lidars, global positioning systems, optical cameras, thermal cameras, ultrasonic sensors, a steering wheel sensor, and/or other sensors.

The vehicle dynamics sensors provide vehicle dynamics data including longitudinal speed, yaw rate, lateral acceleration, longitudinal acceleration, etc. The vehicle dynamics sensors may include wheel sensors that measure information pertaining to one or more wheels of the vehicle 10. In one embodiment, the wheel sensors comprise wheel speed sensors that are coupled to each of the wheels 16, 18 of the vehicle 10. Further, the vehicle dynamics sensors may include one or more accelerometers (provided as part of an Inertial Measurement Unit (IMU)) that measure information pertaining to an acceleration of the vehicle 10. In various embodiments, the accelerometers measure one or more acceleration values for the vehicle 10, including latitudinal and longitudinal acceleration and yaw rate. In at least one embodiment, the vehicle dynamic sensors provide vehicle movement data.

The actuator system 30 includes one or more actuator devices 42a-42n that control one or more vehicle features such as, but not limited to, one or more vehicle wheels 16, 18 the propulsion system 20, the transmission system 22, the steering system 24, and the braking system 26. In various embodiments, the vehicle features can further include interior and/or exterior vehicle features such as, but are not limited to, doors, a trunk, and cabin features such as air, music, lighting, etc. (not numbered).

The communication system 36 is configured to wirelessly communicate information to and from other entities 48, such as but not limited to, other vehicles (“V2V” communication,) infrastructure (“V2I” communication), remote systems, and/or personal devices. In an exemplary embodiment, the communication system 36 is a wireless communication system configured to communicate via a wireless local area network (WLAN) using IEEE 802.11 standards or by using cellular data communication. However, additional, or alternate communication methods, such as a dedicated short-range communications (DSRC) channel, are also considered within the scope of the present disclosure. DSRC channels refer to one-way or two-way short-range to medium-range wireless communication channels specifically designed for automotive use and a corresponding set of protocols and standards.

The data storage device 32 stores data for use in the ADS of the vehicle 10. In various embodiments, the data storage device 32 stores defined maps of the navigable environment. In various embodiments, the defined maps may be predefined by and obtained from a remote system. For example, the defined maps may be assembled by the remote system and communicated to the vehicle 10 (wirelessly and/or in a wired manner) and stored in the data storage device 32. As can be appreciated, the data storage device 32 may be part of the controller 34, separate from the controller 34, or part of the controller 34 and part of a separate system.

The controller 34 includes at least one processor 44 and a computer readable storage device or media 46. The processor 44 can be any custom made or commercially available processor, a central processing unit (CPU), a graphics processing unit (GPU), an auxiliary processor among several processors associated with the controller 34, a semiconductor-based microprocessor (in the form of a microchip or chip set), a macroprocessor, any combination thereof, or generally any device for executing instructions. The computer readable storage device or media 46 may include volatile and nonvolatile storage in read-only memory (ROM), random-access memory (RAM), and keep-alive memory (KAM), for example. KAM is a persistent or non-volatile memory that may be used to store various operating variables while the processor 44 is powered down. The computer-readable storage device or media 46 may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions, used by the controller 34 in controlling the vehicle 10.

The instructions may include one or more separate programs, each of which comprises an ordered listing of executable instructions for implementing logical functions. The instructions, when executed by the processor 44, receive and process signals from the sensor system 28, perform logic, calculations, methods and/or algorithms for automatically controlling the components of the vehicle 10, and generate control signals to the actuator system 30 to automatically control the components of the vehicle 10 based on the logic, calculations, methods, and/or algorithms. Although only one controller 34 is shown in FIG. 1, embodiments of the vehicle 10 can include any number of controllers 34 that communicate over any suitable communication medium or a combination of communication mediums and that cooperate to process the sensor signals, perform logic, calculations, methods, and/or algorithms, and generate control signals to automatically control features of the vehicle 10. In various embodiments, the controller(s) 34 are configured to implement ADS.

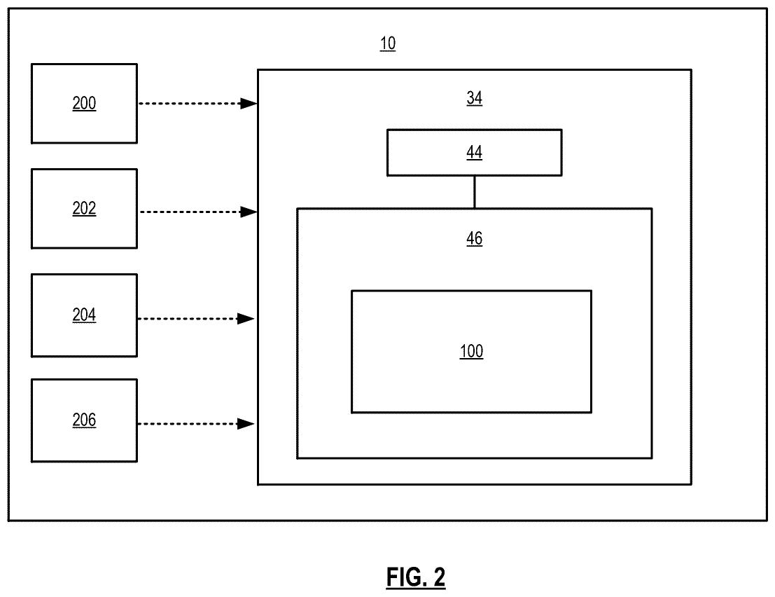

Referring to FIG. 2, a functional block diagram of a controller 34 including a battery internal soft short detection system 100 in accordance with at least one embodiment is shown. The controller 34 includes at least one processor 44 and at least one memory 46. The at least one processor 44 is a programable device that includes one or more instructions stored in or associated with the at least one memory 46. The at least one memory 46 includes instructions that the at least one processor 44 is configured to execute. The at least one memory 46 includes an embodiment of the battery internal soft short detection system 100.

The controller 34 is configured to be communicatively coupled to at least one voltage sensor 200, at least one current sensor 202, at least one temperatures sensor 204, and at least one display device 206. A battery system includes a plurality of battery modules. Each battery module includes a plurality of battery cell groups. The voltage sensors 200 are configured to detect cell group voltage associated with each of the battery cell groups. The current sensors 202 are configured to detect cell group current associated with each of the battery cell groups. The temperature sensors 204 are configured to detect module temperature associated with each of the battery modules. The cell group temperature for each battery cell group is extrapolated from the module temperature for the associated battery module.

Each battery cell group includes a plurality of battery cells. The battery internal soft short detection system 100 is configured to determine whether a battery cell group includes a battery cell that includes an internal soft short based on the cell group voltage, the cell group current, and the cell group temperature for that battery cell group. If the battery internal soft short detection system 100 detects an internal soft short in a battery cell group, the battery internal soft short detection system 100 is configured to generate a battery internal soft short notification associated with that battery cell group for display on the display device 206. The controller 34 shown in FIG. 2 may include additional components that facilitate operation of the battery internal soft short detection system 100. The operation of the battery internal soft short detection system 100 will be described in greater detail below.

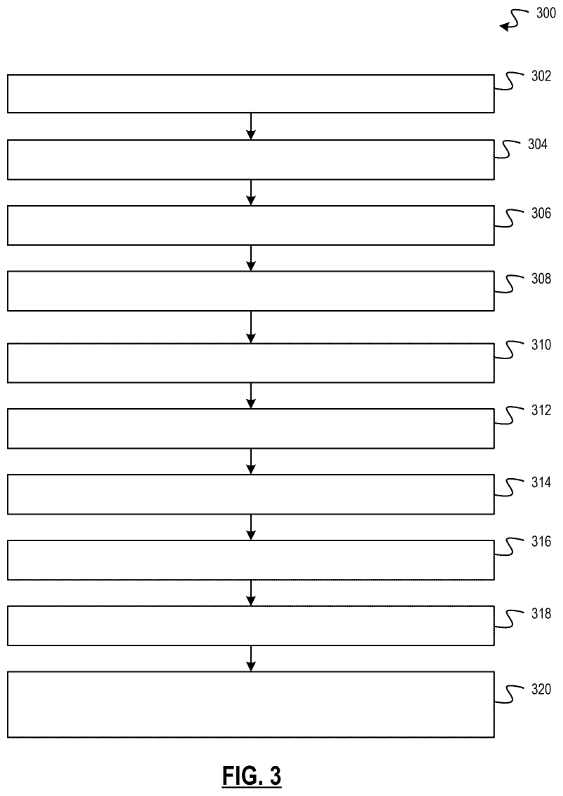

Referring to FIG. 3, a flowchart representation of a method 300 of detecting an internal soft short in a battery cell group in accordance with at least one embodiment is shown. The method 300 will be described with reference to an exemplary implementation of an embodiment of a battery internal soft short detection system 100. As can be appreciated in light of the disclosure, the order of operation within the method 300 is not limited to the sequential execution as illustrated in FIG. 3 but may be performed in one or more varying orders as applicable and in accordance with the present disclosure.

At 302, the battery internal soft short detection system 100 receives cell group voltage, cell group current and cell group temperature associated with the battery cell groups in a battery module. The battery internal soft short detection system 100 receives the cell group voltage from at least one voltage sensor 200 configured to measure cell group voltage of the battery cell group. The battery internal soft short detection system 100 receives the cell group current from at least one current sensor 200 configured to measure cell group current of the battery cell group. The battery internal soft short detection system 100 receives a module temperature from at least one temperature sensor 204 configured to measure the module temperature of the battery module that includes the battery cell group. The cell group temperature for the battery cell group is extrapolated from the module temperature.

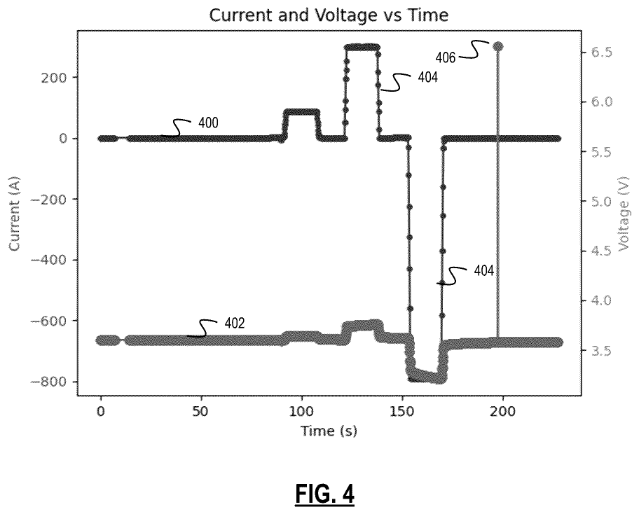

At 304, the battery internal soft short detection system 100 performs current-based segmentation of the received cell group current to identify current pulses in the cell group current. Referring to FIG. 4, a graphical representation of exemplary cell group current 400 and cell group voltage 402 of a battery cell group as a function of time following the performance of current-based segmentation in accordance with at least one embodiment is shown. In at least one embodiment, the battery internal soft short detection system 100 detects rising edges and falling edges in the cell group current that exceed a pre-defined threshold to identify the current pulses 404. The presence of a current pulse 404 in a segment of the cell group current indicates that the battery cell group is either in a state of charging or discharging during the associated time period. The segment of the cell group current where the cell group current is close to zero indicates that the battery cell group is idle during the associated time period.

Referring back to FIG. 3, at 306, the battery internal soft short detection system 100 perform outlier removal of outlier cell group current values and outlier cell group voltage values. The outlier cell group current value is identified by comparing changes in the cell group current to a current outlier threshold. A cell group current value is identified as an outlier cell group current value if associated change is greater than the current outlier threshold. The outlier cell group voltage value is identified by comparing changes in the cell group voltage to a voltage outlier threshold. A cell group voltage value is identified as an outlier cell group voltage value if associated change is greater than the voltage outlier threshold. For example, in FIG. 4, the cell group voltage value 406 has been identified as an outlier cell group voltage value.

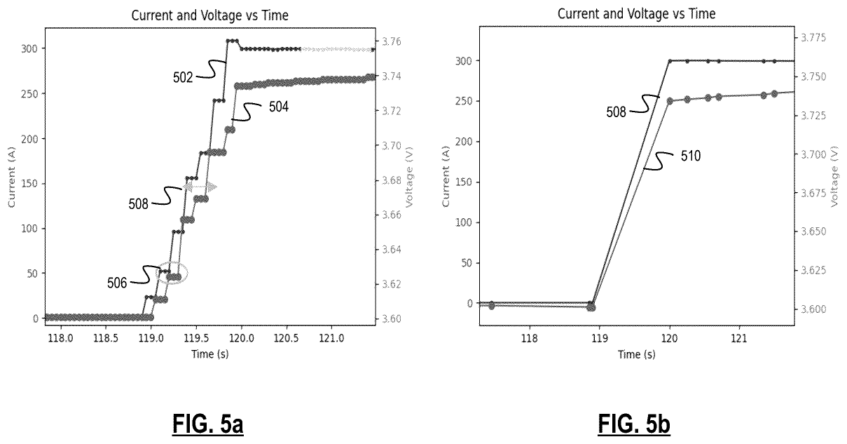

At 308, the battery internal soft short detection system 100 performs down data sample and alignment of the cell group voltage and the cell group current. Referring to FIG. 5a, a graphical representations of exemplary cell group current 502 and cell group voltage 504 as a function of time prior to performance of data down sample and alignment in accordance with at least one embodiment is shown. The cell group current 502 and the cell group voltage 504 include redundant data. An example of redundant data in the cell group current 502 is shown at 506. The cell group current 502 is misaligned with respect to the cell group voltage 504. An example of the misalignment is shown at 508.

Referring to FIG. 5b, a graphical representations of exemplary cell group current 508 and cell group voltage 510 as a function of time following the performance of data down sample and alignment in accordance with at least one embodiment is shown. The redundant data in the cell group current 502 and the cell group voltage 504 have been removed to generate the cell group current 508 and cell group voltage 510. The cell group current 508 and cell group voltage 510 have been aligned following the performance of the alignment of the cell group current 508 and the cell group voltage by the battery internal soft short detection system 100.

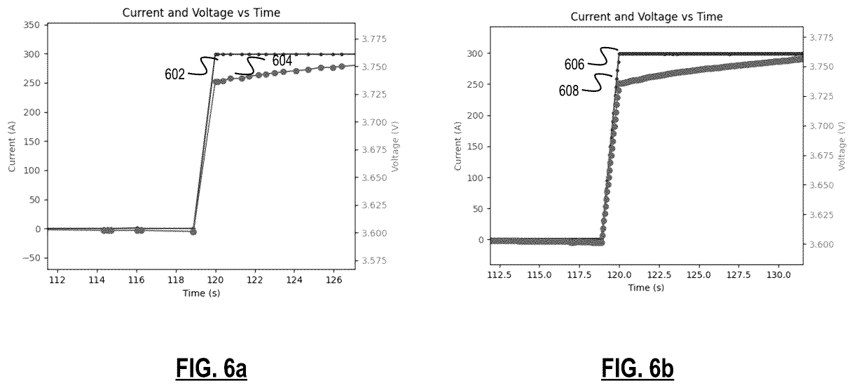

At 310, the battery internal soft short detection system 100 performs linear interpolation of the cell group voltage and the cell group current to address sampling rate issues after the performance of the down data sample. Linear interpolation is performed based on an assumption that a relationship between data points is linear, meaning a straight line can be drawn between them. Referring to FIG. 6a, a graphical representations of exemplary cell group current 602 and cell group voltage 604 as a function of time prior to performance of linear interpolation in accordance with at least one embodiment is shown. Referring to FIG. 6b, a graphical representations of exemplary cell group current 606 and cell group voltage 608 as a function of time following the performance of linear interpolation in accordance with at least one embodiment is shown.

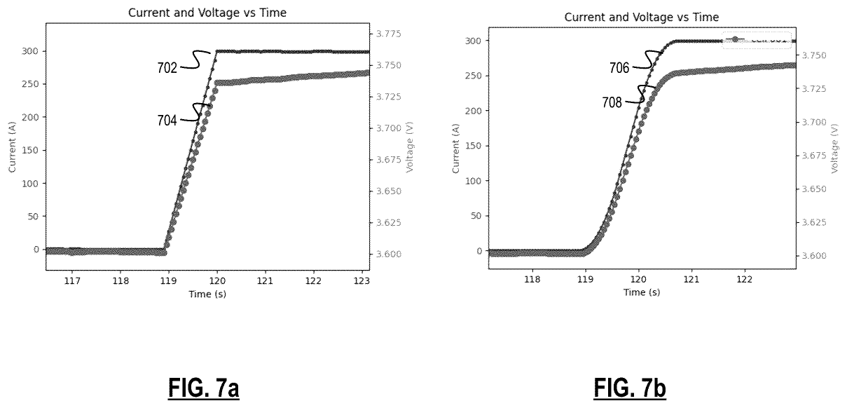

At 312, the battery internal soft short detection system 100 performs low pass filtering of the cell group voltage and the cell group current to address voltage and current variation trend issues following the linear interpolation process. Referring to FIG. 7a, a graphical representations of exemplary cell group current 702 and cell group voltage 704 as a function of time prior to performance of low pass filtering in accordance with at least one embodiment is shown. Referring to FIG. 7b, a graphical representations of exemplary cell group current 706 and cell group voltage 708 as a function of time following performance of low pass filtering in accordance with at least one embodiment is shown.

The battery internal soft short detection system 100 performs data preprocessing of the cell group voltage and the cell group current prior to the generation of health indicators associated with the battery cell group. The data preprocessing includes the performance of the outlier removal at 306, the performance of data down sample and alignment at 308, performance of linear interpolation at 310, and performance of low pass filtering at 312. The data preprocessing of the cell group voltage and the cell group current enables the generation of accurate health indicators associated with the battery cell group.

At 314, the battery internal soft short detection system 100 generates the health indicators associated with the battery cell group. In at least one embodiment, the battery internal soft short detection system 100 uses an equivalent circuit model (ECM) to generate the health indicators based on the cell group voltage and the cell group current. The health indicators are the open circuit voltage (OCV) of the battery cell group and cell group voltage (cgV) of the battery cell group. In at least one embodiment the open circuit voltage OCV of the battery cell group is measured when the cell group current is zero.

At 316, the battery internal soft short detection system 100 performs thermal compensation of the health indicators. The battery internal soft detection system 100 received the module temperature from the at least one temperature sensor 204 configured to measure the module temperature of the battery module that includes the battery cell group. The cell group temperature for the battery cell group was extrapolated from the module temperature. There is a correlation between the health indicators and cell group temperature. The health indicators are thermally compensated in accordance with a correlation to a standard temperature to enable an accurate assessment of the health indicators of the battery cell group.

At 318, the battery internal soft short detection system 100 generates normalized health indicators. The normalized open circuit voltage (mmOCV) of the battery cell group is the open circuit voltage (OCV) of the battery cell group minus a median open circuit voltage (median OCV) of the open circuit voltages (OCV) of all of the battery cell groups in the battery module. The normalized cell group voltage (mmcgV) of the battery cell group is the cell group voltage (cgV) of the battery cell group minus a median cell group voltage (median cgV) of the cell group voltages (cgV) of all of the battery cell groups in the battery module.

At 320, the battery internal soft short detection system 100 determines whether there is an internal soft short in the battery cell group based on the normalized health indicators. The normalized health indicators are the normalized open circuit voltage (mmOCV) of the battery cell group and the normalized cell group voltage (mmcgV) of the battery cell group.

The battery internal soft short detection system 100 determines whether there is an internal soft short in the battery cell group based on the normalized health indicators using a first rule and a second rule. There are two different options for the first rule and there are two different options for the second rule. The first rule is designed to capture an outlier battery cell group in a battery module.

The first option associated with the first rule is defined by the equation below:

$$F = ( \vert z ( mm O C V ) \vert > {T}_{1} ) and ( \vert z ( \frac{d ( mm c g V )}{dt} ) \vert > {T}_{2}$$

The battery internal soft short detection system 100 determines a z-score associated with the normalized open circuit voltage of the battery cell group. The normalized open circuit voltage of the battery cell group is mmOCV in the equation. The z-score is a statistical measure that quantifies the distance between a data point and the mean of a dataset and is expressed in terms of standard deviations. The z-score of the normalized open circuit voltage (mmOCV) of the battery cell group represents the number of standard deviations of the normalized open circuit voltage (mmOCV) of the battery cell group with respect to a mean value of the open circuit voltages (OCV) of all of the battery cell groups in the battery module. The battery internal soft short detection system 100 determines whether an absolute value of the z-score of the normalized open circuit voltage (mmOCV) of the battery cell group is greater than a threshold number of standard deviations T₁. An example of a threshold number of standard deviations T₁ is three.

The battery internal soft short detection system 100 determines a z-score associated with a rate of change of the normalized cell group voltage (mmcgV) of the battery cell group as a function of time. The normalized cell group voltage of the battery cell group is mmcgV in the equation. The z-score of the rate of change of the normalized cell group voltage of the battery cell group represents the number of standard deviations of the rate of change of the normalized cell group voltage (mmcgV) of the battery cell group with respect to a mean value of the rate of change of the cell group voltages (cgV) of all of the battery cell groups in the battery module. The battery internal soft short detection system 100 determines whether an absolute value of the z-score of the rate of change of the normalized cell group voltage (mmcgV) of the battery cell group is greater than a threshold number of standard deviations T₂. An example of a threshold number of standard deviations T₂ is three.

If the battery internal soft short detection system 100 determines that the absolute value of the z-score of the normalized open circuit voltage (mmOCV) of the battery cell group is greater than the threshold number of standard deviations T₁ and the absolute value of the z-score of the rate of change of the normalized cell group voltage (mmcgV) of the battery cell group is greater than the threshold number of standard deviations T₂, the first rule is determined to be true.

The second option associated with the first rule is defined by the equation below

$$F = ( \vert z ( mmOCV ) \vert > {T}_{1} ) and \vert z ( Δ mmcgV ) \vert > {T}_{3} during pulse$$

The battery internal soft short detection system 100 determines a z-score associated with the normalized open circuit voltage of the battery cell group. The normalized open circuit voltage of the battery cell group is mmOCV in the equation. The z-score of the normalized open circuit voltage (mmOCV) of the battery cell group represents the number of standard deviations of the normalized open circuit voltage (mmOCV) of the battery cell group with respect to a mean value of the open circuit voltages (OCV) of all of the battery cell groups in the battery module. The battery internal soft short detection system 100 determines whether an absolute value of the z-score of the normalized open circuit voltage (mmOCV) of the battery cell group is greater than a threshold number of standard deviations T₁. An example of a threshold number of standard deviations T₁ is three.

The battery internal soft short detection system 100 determines a change in the normalized cell group voltage (mmcgV) of the battery cell group during a pulse that was detected during the current-based segmentation. In an alternative embodiment, the pulse may be a test pulse applied to the battery cell group. The battery internal soft short detection system 100 determines a z-score associated with a change in the normalized cell group voltage (mmcgV) of the battery cell group during the pulse. The normalized cell group voltage of the battery cell group is mmcgV in the equation. The z-score of the change in the normalized cell group voltage of the battery cell group represents the number of standard deviations of the change in the normalized cell group voltage (mmcgV) of the battery cell group with respect to a mean value of the change in the cell group voltages (cgV) of all of the battery cell groups in the battery module. The battery internal soft short detection system 100 determines whether an absolute value of the z-score of the change in the normalized cell group voltage of the battery cell group is greater than a threshold number of standard deviations T₃. An example of a threshold number of standard deviations T₃ is three.

If the battery internal soft short detection system 100 determines that the absolute value of the z-score of the normalized open circuit voltage (mmOCV) of the battery cell group is greater than the threshold number of standard deviations T₁ and the absolute value of the z-score of the change in the normalized cell group voltage of the battery cell group is greater than the threshold number of standard deviations T₃ the first rule is determined to be true.

The first option associated with the second rule is defined by the equation below:

$$F = ( mmOCV < {T}_{4} ) and ( \vert \frac{d ( mmcgV )}{dt} \vert > {T}_{5} )$$

The normalized open circuit voltage of the battery cell group is mmOCV in the equation. The normalized cell group voltage of the battery cell group is mmcgV in the equation. The battery internal soft short detection system 100 determines whether the normalized open circuit voltage of the battery cell group (mmOCV) is less than a threshold T₄. The normalized cell group voltage of the battery cell group (mmOCV) being less than the threshold T₄ indicates that the battery cell group has a low state of change (SOC). The battery internal soft short detection system 100 determines whether the absolute value of the rate of change of the normalized cell group voltage of the battery cell group (mmcgV) with respect to time is greater than a threshold T₅.

If the battery internal soft short detection system 100 determines that the normalized open circuit voltage of the battery cell group (mmOCV) is less than a threshold T₄ and the absolute value of the rate of change of the normalized cell group voltage of the battery cell group (mmcgV) with respect to time is greater than a threshold T₅, the second rule is determined to be true.

The second option associated with the second rule is defined by the equation below:

$$F = ( mmOCV < {T}_{4} ) and ( \vert Δ mmcgV \vert > {T}_{6} ) during pulse$$

The normalized open circuit voltage of the battery cell group is mmOCV in the equation. The normalized cell group voltage of the battery cell group is mmcgV in the equation. The battery internal soft short detection system 100 determines whether the normalized open circuit voltage of the battery cell group (mmOCV) is less than a threshold T₄. The normalized cell group voltage of the battery cell group (mmOCV) being less than the threshold T₄ indicates that the battery cell group has a low state of change (SOC).

The battery internal soft short detection system 100 determines a change in the normalized cell group voltage (mmcgV) of the battery cell group during a pulse that was detected during the current-based segmentation. In an alternative embodiment, the pulse may be a test pulse applied to the battery cell group. The battery internal soft short detection system 100 determines whether an absolute value of the change in the normalized cell group voltage (mmcgV) of the battery cell group during a pulse is greater than a threshold T₆.

If the battery internal soft short detection system 100 determines that the normalized open circuit voltage of the battery cell group (mmOCV) is less than the threshold T₄ and the absolute value of the change in the normalized cell group voltage (mmcgV) of the battery cell group during a pulse is greater than a threshold T₆, the second rule is determined to be true.

If the battery internal soft short detection system 100 determines the first rule and the second rule to be true for a battery cell group, the battery internal soft short detection system 100 determines that a fault has been detected in that battery cell group. The battery internal soft short detection system 100 determines that at least one battery cell in the battery cell group is experiencing an internal soft short. The battery internal soft short detection system 100 generate a battery internal soft short notification associated with that battery cell group for display on the display device 206.

In at least one embodiment, a t-score may be used instead of the z-score in the equations above. A t-score represents how many standard deviations a data point is away from the mean in a t-distribution.

In at least one embodiment, an equivalent circuit model (ECM) RI can be used to replace ΔmmcgV in the equations above. The ECM RI is a type of ECM that can be used to monitor and control lithium-ion batteries. ECMs are used often used in battery management systems.

While the use of the battery internal soft short detection system 100 has been described with respect to lithium-ion batteries, in alternative embodiments, the battery internal soft short detection system 100 may be used to detect internal soft shorts in other types of batteries. Examples of other batteries include, but are not limited to, nickel-metal hydride (NiMH) batteries, sealed lead-acid batteries, sodium ion batteries, zinc-air batteries, flow batteries, and alkaline batteries.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A battery internal soft short detection system comprising:
at least one processor; and
at least one memory communicatively coupled to the at least one processor, the at least one memory comprising instructions that upon execution by the at least one processor, cause the at least one processor to:
receive cell group voltages for a plurality of battery cell groups of a battery module from a plurality of voltage sensors;
receive cell group currents for the plurality of battery cell groups from a plurality of current sensors;
generate open circuit voltages for each of the plurality of battery cell groups based on the cell group voltages and the cell group currents;
generate a normalized open circuit voltage of a first battery cell group of the plurality of battery cell groups based on the open circuit voltages of the plurality of battery cell groups;
generate a normalized cell group voltage of the first battery cell group based on the cell group voltages of the plurality of battery cell groups; and
determine whether there is an internal soft short in the first battery cell group based on an assessment of the normalized open circuit voltage and the normalized cell group voltage of the first battery cell group.

2. The system of claim 1, wherein the at least one memory further comprises instructions that upon execution by the at least one processor, cause the at least one processor to during the assessment:
determine whether a first rule is true based on one of at least one of a first equation and a second equation being true,
the first equation being:
$$F = ( \vert z ( mmOCV ) \vert > {T}_{1} ) and ( \vert z ( \frac{d ( mmcgV )}{dt} ) \vert > {T}_{2}$$
wherein mmOCV is the normalized open circuit voltage of the first battery cell group, T₁ is a first threshold number of standard deviations, mmcgV is the normalized cell group voltage of the first battery cell group, and T₂ is a second threshold number of standard deviations;
the second equation being:
$$F = ( \vert z ( mmOCV ) \vert > {T}_{1} ) and \vert z ( Δ mmcgV ) \vert > {T}_{3}$$
wherein a cell group voltage pulse is detected in a cell group voltage of the first battery cell group and the change in the normalized cell group voltage of the first battery cell group is associated with the cell group voltage pulse, and the T₃ is a third threshold number of standard deviations; and
identify the first battery cell group as an outlier battery cell group in the battery module based on the first rule being true.

3. The system of claim 2, wherein the at least one memory further comprises instructions that upon execution by the at least one processor, cause the at least one processor to during the assessment:
determine whether a second rule is true based on one of at least one of a third equation and a fourth equation being true,
the third equation being:
$$F = ( mmOCV < {T}_{4} ) and ( \vert \frac{d ( mmcgV )}{dt} \vert > {T}_{5} )$$
wherein T₄ is a normalized open circuit voltage threshold and T₅ is a rate of change of a normalized cell group voltage threshold;
the fourth equation being:
$$F = ( mmOCV < {T}_{4} ) and ( \vert Δ mmcgV \vert > {T}_{6} )$$
wherein T₆ is a change in normalized cell group voltage threshold; and
determine that there is the internal soft short in the first battery cell group based the first rule and the second rule being true.

4. The system of claim 1, wherein the at least one memory further comprises instructions that upon execution by the at least one processor, cause the at least one processor to perform outlier removal of outlier cell group voltage values from a cell group voltage associated with the first battery cell group prior to generation of the normalized cell group voltage of the first battery cell group.

5. The system of claim 1, wherein the at least one memory further comprises instructions that upon execution by the at least one processor, cause the at least one processor to perform data down sample and alignment of a cell group voltage and a cell group current associated with the first battery cell group prior to generation of the normalized cell group voltage of the first battery cell group.

6. The system of claim 5, wherein the at least one memory further comprises instructions that upon execution by the at least one processor, cause the at least one processor to perform linear interpolation of the cell group voltage and the cell group current associated with the first battery cell group prior to generation of the normalized cell group voltage of the first battery cell group.

7. The system of claim 6, wherein the at least one memory further comprises instructions that upon execution by the at least one processor, cause the at least one processor to perform low pass filtering of the cell group voltage and the cell group current associated with the first battery cell group prior to generation of the normalized first cell group voltage of the first battery cell group.

8. The system of claim 1, wherein the at least one memory further comprises instructions that upon execution by the at least one processor, cause the at least one processor to perform thermal compensation of an open circuit voltage the first battery cell group prior to generation of the normalized open circuit voltage.

9. A method of detecting an internal soft short in a battery cell group comprising:
receiving cell group voltages for a plurality of battery cell groups of a battery module from a plurality of voltage sensors;
receiving cell group currents for the plurality of battery cell groups from a plurality of current sensors;
generating open circuit voltages for each of the plurality of battery cell groups based on the cell group voltages and the cell group currents;
generating a normalized open circuit voltage of a first battery cell group of the plurality of battery cell groups based on the open circuit voltages of the plurality of battery cell groups;
generating a normalized cell group voltage of the first battery cell group based on the cell group voltages of the plurality of battery cell groups; and
determining whether there is an internal soft short in the first battery cell group based on an assessment of the normalized open circuit voltage and the normalized cell group voltage of the first battery cell group.

10. The method of claim 9, further comprising:
during the assessment, determining whether a first rule is true based on one of at least one of a first equation and a second equation being true,
the first equation being:
$$F = ( \vert z ( mmOCV ) \vert > {T}_{1} ) and ( \vert z ( \frac{d ( mmcgV )}{dt} ) \vert > {T}_{2}$$
wherein mmOCV is the normalized open circuit voltage of the first battery cell group, T₁ is a first threshold number of standard deviations, mmcgV is the normalized cell group voltage of the first battery cell group, and T₂ is a second threshold number of standard deviations;
the second equation being:
$$F = ( \vert z ( mmOCV ) \vert > {T}_{1} ) and \vert z ( Δ mmcgV ) \vert > {T}_{3}$$
wherein a cell group voltage pulse is detected in a cell group voltage of the first battery cell group and the change in the normalized cell group voltage of the first battery cell group is associated with the cell group voltage pulse, and the T₃ is a third threshold number of standard deviations; and
identifying the first battery cell group as an outlier battery cell group in the battery module based on the first rule being true.

11. The method of claim 10, further comprising:
during the assessment, determining whether a second rule is true based on one of at least one of a third equation and a fourth equation being true,
the third equation being:
$$F = ( mmOCV < {T}_{4} ) and ( \vert \frac{d ( mmcgV )}{dt} \vert > {T}_{5} )$$
wherein T₄ is a normalized open circuit voltage threshold and T₅ is a rate of change of a normalized cell group voltage threshold;
the fourth equation being:
$$F = ( mmOCV < {T}_{4} ) and ( \vert Δ mmcgV \vert > {T}_{6} )$$
wherein T₆ is a change in normalized cell group voltage threshold; and
determining that there is the internal soft short in the first battery cell group based the first rule and the second rule being true.

12. The method of claim 9, further comprising performing outlier removal of outlier cell group voltage values from a cell group voltage associated with the first battery cell group prior to generation of the normalized cell group voltage of the first battery cell group.

13. The method of claim 9, further comprising performing data down sample and alignment of a cell group voltage and a cell group current associated with the first battery cell group prior to generation of the normalized cell group voltage of the first battery cell group.

14. The method of claim 13, further comprising performing linear interpolation of the cell group voltage and the cell group current associated with the first battery cell group prior to generation of the normalized cell group voltage of the first battery cell group.

15. The method of claim 14, further comprising performing low pass filtering of the cell group voltage and the cell group current associated with the first battery cell group prior to generation of the normalized first cell group voltage of the first battery cell group.

16. The method of claim 9, further comprising performing thermal compensation of an open circuit voltage the first battery cell group prior to generation of the normalized open circuit voltage.

17. A vehicle including a battery internal soft short detection system comprising:
at least one processor; and
at least one memory communicatively coupled to the at least one processor, the at least one memory comprising instructions that upon execution by the at least one processor, cause the at least one processor to:
receive cell group voltages for a plurality of battery cell groups of a battery module from a plurality of voltage sensors;
receive cell group currents for the plurality of battery cell groups from a plurality of current sensors;
generate open circuit voltages for each of the plurality of battery cell groups based on the cell group voltages and the cell group currents;
generate a normalized open circuit voltage of a first battery cell group of the plurality of battery cell groups based on the open circuit voltages of the plurality of battery cell groups;
generate a normalized cell group voltage of the first battery cell group based on the cell group voltages of the plurality of battery cell groups; and
determine whether there is an internal soft short in the first battery cell group based on an assessment of the normalized open circuit voltage and the normalized cell group voltage of the first battery cell group.

18. The vehicle of claim 17, wherein the at least one memory further comprises instructions that upon execution by the at least one processor, cause the at least one processor to during the assessment:
determine whether a first rule is true based on one of at least one of a first equation and a second equation being true,
the first equation being:
$$F = ( \vert z ( mmOCV ) \vert > {T}_{1} ) and ( \vert z ( \frac{d ( mmcgV )}{dt} ) \vert > {T}_{2}$$
wherein mmOCV is the normalized open circuit voltage of the first battery cell group, T₁ is a first threshold number of standard deviations, mmcgV is the normalized cell group voltage of the first battery cell group, and T₂ is a second threshold number of standard deviations;
the second equation being:
$$F = ( \vert z ( mmOCV ) \vert > {T}_{1} ) and \vert z ( Δ mmcgV ) \vert > {T}_{3}$$
wherein a cell group voltage pulse is detected in a cell group voltage of the first battery cell group and the change in the normalized cell group voltage of the first battery cell group is associated with the cell group voltage pulse, and the T₃ is a third threshold number of standard deviations; and
identify the first battery cell group as an outlier battery cell group in the battery module based on the first rule being true.

19. The vehicle of claim 18, wherein the at least one memory further comprises instructions that upon execution by the at least one processor, cause the at least one processor to during the assessment:
determine whether a second rule is true based on one of at least one of a third equation and a fourth equation being true,
the third equation being:
$$F = ( mmOCV < {T}_{4} ) and ( \vert \frac{d ( mmcgV )}{dt} \vert > {T}_{5} )$$
wherein T₄ is a normalized open circuit voltage threshold and T₅ is a rate of change of a normalized cell group voltage threshold;
the fourth equation being:
$$F = ( mmOCV < {T}_{4} ) and ( \vert Δ mmcgV \vert > {T}_{6} )$$
wherein T₆ is a change in normalized cell group voltage threshold; and
determine that there is the internal soft short in the first battery cell group based the first rule and the second rule being true.

20. The vehicle of claim 17, wherein the at least one memory further comprises instructions that upon execution by the at least one processor, cause the at least one processor to perform data down sample and alignment of a cell group voltage and a cell group current associated with the first battery cell group prior to generation of the normalized cell group voltage of the first battery cell group.
